(19) United States
(12) Patent Application Publication
(10) Pub. No.: US 2025/0384940 A1
(43) Pub. Date: Dec. 18, 2025

(54) LEVEL-BY-LEVEL TOUCH-UP PROGRAMMING IN A MEMORY DEVICE

(71) Applicant: Micron Technology, Inc., Boise, ID (US)

(72) Inventors: Huai-Yuan Tseng, San Ramon, CA (US); Koichi Kawai, Yokohama (JP); Eric Nien-Heng Lee, San Jose, CA (US); Yoshihiko Kamata, Yokohama (JP); Akira Goda, Tokyo (JP)

(21) Appl. No.: 19/236,218

(22) Filed: Jun. 12, 2025

Related U.S. Application Data
(60) Provisional application No. 63/660,405, filed on Jun. 14, 2024.

(51) Int. Cl. G11C 16/34; G11C 16/10; G11C 16/26

(52) U.S. Cl. CPC G11C 16/3459; G11C 16/102; G11C 16/26

(57) ABSTRACT

Control logic in a memory device causes a primary program operation to be initiated on the memory array. The primary program operation includes multiple primary program pulses and corresponding verify pulses. The control logic causes a secondary program operation to be initiated on the memory array. The secondary program operation includes causing multiple sensing pulses to be applied to the memory array to determine a plurality of measured threshold voltages corresponding to the memory array, determining bitline voltages based on the multiple measured threshold voltages, causing the bitline voltages to be applied to at least one set of cells of the plurality of memory cells, and causing multiple secondary program pulses to be applied to the at least one set of cells.

### CLAIM OF PRIORITY

The present application claims the benefit under 35 U.S.C. § 119 (e) of U.S. Provisional Patent Application No. 63/660,405 filed Jun. 14, 2024, which is incorporated by reference herein.

### TECHNICAL FIELD

Embodiments of the disclosure relate generally to memory sub-systems, and more specifically, relate to level-by-level touch-up programming in a memory device of a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1A illustrates an example computing system that includes a memory sub-system, according to some aspects of the disclosure.

FIG. 1B is a simplified block diagram of a first apparatus, in the form of a memory device, in communication with a second apparatus, in the form of a memory sub-system controller of a memory sub-system, according to some aspects of the disclosure.

FIG. 2 is a schematic of portions of an array of memory cells, such as a NAND memory array, according to some aspects of the disclosure.

FIG. 3A and FIG. 3B illustrate a primary program operation and a secondary program operation, according to some aspects of the disclosure.

FIG. 4 is a flow diagram of an example method for level-by-level touch-up programming in a memory device of a memory sub-system according to some aspects of the disclosure.

FIG. 5A and FIG. 5B are flow diagrams of an example method for level-by-level touch-up programming in a memory device of a memory sub-system, according to some aspects of the disclosure.

FIG. 6 is a block diagram of an example computer system in which embodiments of the disclosure may operate.

### DETAILED DESCRIPTION

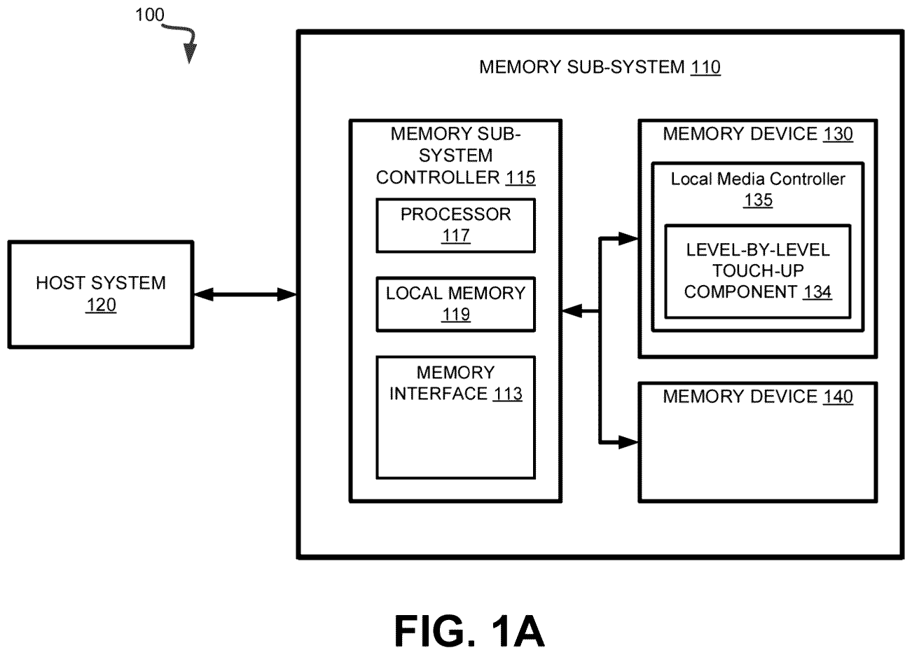

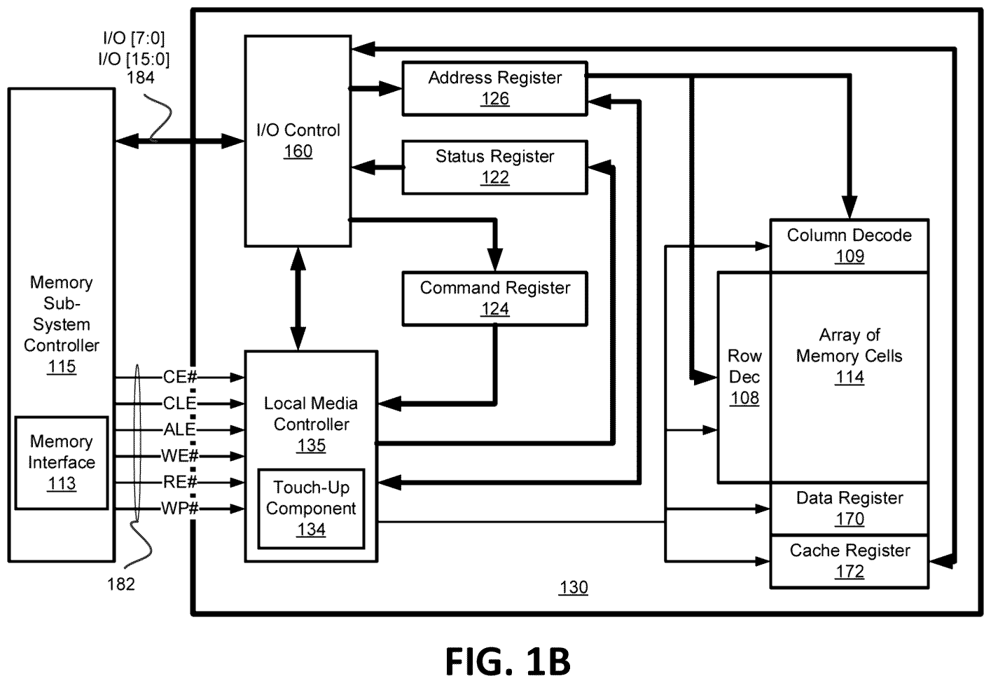

Aspects of the present disclosure are directed to level-by-level touch-up programming in a memory device of a memory sub-system. A memory sub-system can be a storage device, a memory module, or a combination of a storage device and memory module. Examples of storage devices and memory modules are described below in conjunction with FIG. 1A. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a not-and (NAND) memory device. Other examples of non-volatile memory devices are described below in conjunction with FIG. 1A. A non-volatile memory device is a package of one or more dies. Each die can include of one or more planes. For some types of non-volatile memory devices (e.g., NAND devices), each plane includes of a set of physical blocks. Each block includes of a set of pages. Each page includes of a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device can be made up of bits arranged in a two-dimensional or a three-dimensional grid. Memory cells are formed onto a silicon wafer in an array of columns (also hereinafter referred to as bitlines) and rows (also hereinafter referred to as wordlines). A wordline can have a row of associated memory cells in a memory device that are used with one or more bitlines to generate the address of each of the memory cells. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form separate partitions (e.g., planes) of the memory device in order to allow concurrent operations to take place on each plane. The memory device can include circuitry that performs concurrent memory page accesses of two or more memory planes. For example, the memory device can include multiple access line driver circuits and power circuits that can be shared by the planes of the memory device to facilitate concurrent access of pages of two or more memory planes, including different page types. For case of description, these circuits can be generally referred to as independent plane driver circuits. Depending on the storage architecture employed, data can be stored across the memory planes (i.e., in stripes). Accordingly, one request to read a segment of data (e.g., corresponding to one or more data addresses), can result in read operations performed on two or more of the memory planes of the memory device.

During certain memory access operations, selective slow program convergence (SSPC) can be used to improve a program threshold voltage distribution width (e.g., the width between voltage (Vt) distributions) on the memory device. In SSPC, or level-by-level programming, the memory cells are programmed with incrementally increased program pulses applied to wordlines to which the memory cells are coupled. After each program pulse, a program verify pulse determines a threshold voltage for the most recently programmed cell. As the threshold voltage for a particular cell approaches a desired voltage threshold, the bitline connected to the particular cell is biased with a voltage that slows down the change in the Vt of the cell. Cells without a biased bitline continue to be programmed at their normal pace. When the Vt for the cell reaches the desired voltage threshold, the bitline is biased with an inhibit voltage to prevent the Vt of the cell from continuing to change. To improve performance, an analog voltage may be applied to the bitlines connected to cells being programmed with SSPC.

After a level-by-level programming is performed, a touch-up program operation can be performed to narrow the respective voltage distributions of the programmed cells (e.g., increase the read-window budget (RWB). In some touch-up program operations, program verify operations performed after after program pulses can determine the threshold voltage for each previously programmed voltage distribution. For example, after a program pulse for a level three (L3) cell, the following program verify operation can include a first program verify pulse for the level one (L1) cell, a second program verify pulse for the level two (L2) cell, and a third program verify pulse for the level three (L3) cell. In this approach, performing program verifies for previously programmed cells during the touch-up program operation can substantially increase the overall programming time, and the duration between program pulses (especially for higher Vt distributions).

Aspects of the present disclosure address the above and other deficiencies by providing a memory sub-system that can perform level-by-level touch-up programming in a memory device. The level-by-level touch-up program operation can be a similar operation as the initial level-by-level program operation, and can be performed immediately after the initial program operation, or a short or long duration after the initial program operation. By applying the same techniques to the touch-up program operation, the overall programming time can be significantly reduced (e.g., by reducing the quantity of program pulses and verify pulses performed during the touch-up program operation).

The level-by-level touch-up program operation can perform a series of program verify pulses followed by corresponding touch-up program pulses. The program verify can determine which memory cells associated with a voltage distribution have a voltage value below the voltage threshold associated with the voltage distribution. The cells of the voltage distribution can have an analog bitline applied during the following touch-up program pulse that allows cells with voltage values below the threshold voltage to increase closer to the voltage threshold, and cells with voltage values at or above the threshold voltage to remain near to the threshold voltage. In some embodiments, the analog voltage is selected based on the quantity of cells below the threshold voltage of the voltage distribution, and/or the voltage values of the cells with voltage values below the threshold voltage. In some embodiments, a level-by-level touch-up program operation can be performed for a particular wordline after one or more program operations have been performed for additional wordlines. That is, a program operation can be performed on a first wordline, and then a second wordline (or multiple wordlines). After the program operation is performed on the second wordline, the level-by-level touch-up program operation can be performed on the first wordline.

Advantages of this approach include, but are not limited to, improved performance in the memory sub-system. The time and power required to perform program operations can be reduced. In addition, level-by-level touch-up programming can increase the RWB between the voltage distribution, resulting in, among other improvements, improved memory device stability over time.

FIG. 1A illustrates an example computing system 100 that includes a memory sub-system 110 in accordance with some aspects of the disclosure. The memory sub-system 110 can include media, such as one or more volatile memory devices (e.g., memory device 140), one or more non-volatile memory devices (e.g., the memory device 130), or a combination of such.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe or CXL bus). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., the memory device 130) include a not-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 130 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, or electrically erasable programmable read-only memory (EEPROM).

A memory sub-system controller 115 can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which is a raw the memory device 130 having control logic (e.g., local media controller 135) on the die and a controller (e.g., memory sub-system controller 115) for media management within the same memory device package. An example of a managed memory device is a managed NAND (MNAND) device.

The memory sub-system 110 includes a memory interface component 113. Memory interface component 113 is responsible for handling interactions of the memory sub-system controller 115 with the memory devices of the memory sub-system 110, such as the memory device 130. For example, memory interface component 113 can send memory access commands corresponding to requests received from host system 120 to the memory device 130, such as program commands, read commands, or other commands. In addition, memory interface component 113 can receive data from the memory device 130, such as data retrieved in response to a read command or a confirmation that a program command was successfully performed. In some embodiments, the memory sub-system controller 115 includes at least a portion of the memory interface component 113. For example, the memory sub-system controller 115 can include a processor 117 (e.g., a processing device) configured to execute instructions stored in local memory 119 for performing the operations described herein. In some embodiments, the memory interface component 113 is part of the host system 120, an application, or an operating system.

In some embodiments, the memory device 130 includes the level-by level touch-up level-by-level touch-up component 134. The level-by-level touch-up component 134 is configured to carry out memory access operations in response to receiving memory access commands from the touch-up manager component 114. In some embodiments, local media controller includes at least a portion of level-by-level touch-up component 134 and is configured to perform the functionality described herein. In some embodiments, level-by-level touch-up component 134 is implemented on the memory device 130 using firmware, hardware components, or a combination of the above.

In some embodiments, after a primary program operation, level-by-level touch-up component 134 initiates a secondary program operation on the same set of cells programmed by the primary program operation. The secondary program operation can include sensing pulses and corresponding program pulses (e.g., touch-up program pulses). The level-by-level touch-up component 134 can apply a bitline voltage to be applied to memory cells based on the measured voltages of the memory cells during the secondary program operation. This series of verify pulses followed by touch-up program pulses can cause a previously programmed voltage distribution to narrow by increasing the voltage values of cells below a threshold voltage associated with a respective voltage distribution of the memory device. In some embodiments, the level-by-level touch-up component 134 can work in conjunction with a programming component (not illustrated) to perform the touch-up program operation. In some embodiments, the level-by-level touch-up component 134 can include a timer or counter that is initialized when a particular wordline is programmed by a primary program operation. Once the timer or counter reaches a threshold (e.g., a number of intermediate program operations, duration of time since the primary program operation was performed, etc.), the level-by-level touch-up component 134 can initiate the secondary program operation on the particular wordline.

FIG. 1B is a simplified block diagram of a first apparatus, in the form of the memory device 130, in communication with a second apparatus, in the form of a memory sub-system controller 115 of a memory sub-system (e.g., memory sub-system 110 of FIG. 1A), according to some aspects of the disclosure. Some examples of electronic systems include personal computers, personal digital assistants (PDAs), digital cameras, digital media players, digital recorders, games, appliances, vehicles, wireless devices, mobile telephones, and the like. The memory sub-system controller 115 (e.g., a controller external to the memory device 130), may be a memory controller or other external host device. In one embodiment, memory sub-system controller 115 includes touch-up manager component 114.

The memory device 130 includes an array of memory cells (memory array 114) logically arranged in rows and columns. Memory cells of a logical row are typically connected to the same access line (e.g., a wordline) while memory cells of a logical column are typically selectively connected to the same data line (e.g., a bit line). A single access line may be associated with more than one logical row of memory cells and a single data line may be associated with more than one logical column. Memory cells (not shown in FIG. 1B) of at least a portion of the memory array 114 are capable of being programmed to one of at least two target data states.

Row decode circuitry 108 and column decode circuitry 109 are provided to decode address signals. Address signals are received and decoded to access the memory array 114. The memory device 130 also includes input/output (I/O) control circuitry 160 to manage input of commands, addresses and data to the memory device 130 as well as output of data and status information from the memory device 130. An address register 126 is in communication with I/O control circuitry 160 and row decode circuitry 108 and column decode circuitry 109 to latch the address signals prior to decoding. A command register 124 is in communication with I/O control circuitry 160 and local media controller 135 to latch incoming commands.

A controller (e.g., the local media controller 135 internal to the memory device 130) controls access to the memory array 114 in response to the commands and generates status information for the memory sub-system controller 115, i.e., the local media controller 135 is configured to perform access operations (e.g., read operations, programming operations and/or erase operations) on the memory array 114. The local media controller 135 is in communication with row decode circuitry 108 and column decode circuitry 109 to control the row decode circuitry 108 and column decode circuitry 109 in response to the addresses. In one embodiment, local media controller 135 includes suspend level-by-level touch-up component 134.

The local media controller 135 is also in communication with a cache register 172. Cache register 172 latches data, either incoming or outgoing, as directed by the local media controller 135 to temporarily store data while the memory array 114 is busy writing or reading, respectively, other data. During a program operation (e.g., write operation), data may be passed from the cache register 172 to the data register 170 for transfer to the memory array 114; then new data may be latched in the cache register 172 from the I/O control circuitry 160. During a read operation, data may be passed from the cache register 172 to the I/O control circuitry 160 for output to the memory sub-system controller 115; then new data may be passed from the data register 170 to the cache register 172. The cache register 172 and/or the data register 170 may form (e.g., may form a portion of) a page buffer of the memory device 130. A page buffer may further include sensing devices (not shown in FIG. 1B) to sense a data state of a memory cell of the memory array 114, e.g., by sensing a state of a data line connected to that memory cell. A status register 122 may be in communication with I/O control circuitry 160 and the local media controller 135 to latch the status information for output to the memory sub-system controller 115.

The memory device 130 receives control signals at the memory sub-system controller 115 from the local media controller 135 over a control link 182. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) may be further received over control link 182 depending upon the nature of the memory device 130. In one embodiment, the memory device 130 receives command signals (which represent commands), address signals (which represent addresses), and data signals (which represent data) from the memory sub-system controller 115 over a multiplexed input/output (I/O) bus 184 and outputs data to the memory sub-system controller 115 over I/O bus 184.

For example, the commands may be received over input/output (I/O) pins [7:0] of I/O bus 184 at I/O control circuitry 160 and may then be written into command register 124. The addresses may be received over input/output (I/O) pins [7:0] of I/O bus 184 at I/O control circuitry 160 and may then be written into address register 126. The data may be received over input/output (I/O) pins [7:0] for an 8-bit device or input/output (I/O) pins [15:0] for a 16-bit device at I/O control circuitry 160 and then may be written into cache register 172. The data may be subsequently written into data register 170 for programming the memory array 114.

In an embodiment, cache register 172 may be omitted, and the data may be written directly into data register 170. Data may also be output over input/output (I/O) pins [7:0] for an 8-bit device or input/output (I/O) pins [15:0] for a 16-bit device. Although reference may be made to I/O pins, they may include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIG. 1B has been simplified. It should be recognized that the functionality of the various block components described with reference to FIG. 1B may not necessarily be segregated to distinct components or component portions of an integrated circuit device. For example, a single component or component portion of an integrated circuit device could be adapted to perform the functionality of more than one block component of FIG. 1B. Alternatively, one or more components or component portions of an integrated circuit device could be combined to perform the functionality of a single block component of FIG. 1B. Additionally, while specific I/O pins are described in accordance with popular conventions for receipt and output of the various signals, it is noted that other combinations or numbers of I/O pins (or other I/O node structures) may be used in the various embodiments.

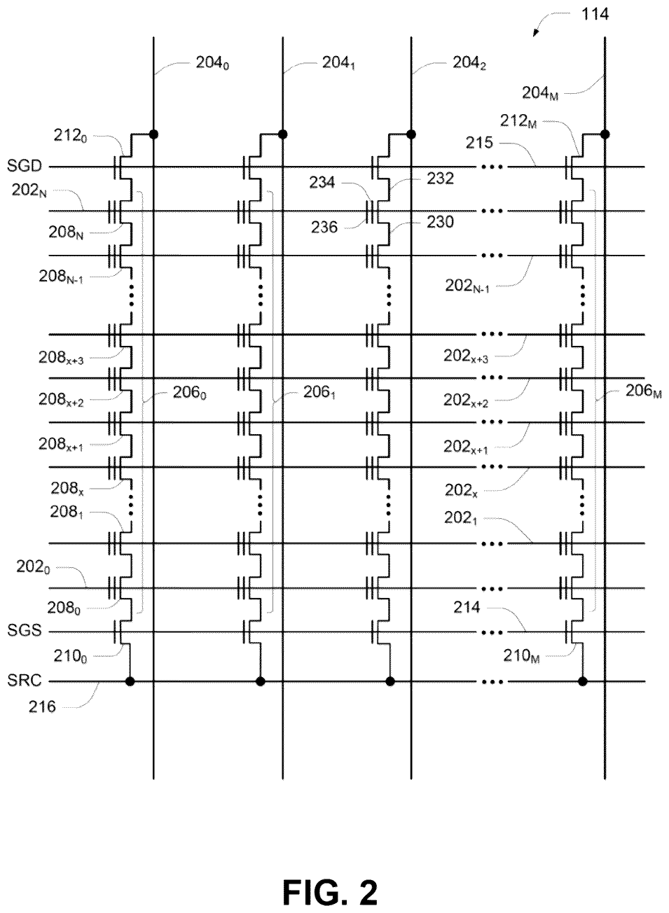

FIG. 2 is a schematic of portions of an memory array 114, such as a NAND memory array, as could be used in a memory of the type described with reference to FIG. 1B according to some aspects of the disclosure. Memory array 114 includes access lines, such as wordlines 2020 to 202_{N}, and data lines, such as bit lines 204₀ to 204_{M}. The wordlines 202 can be connected to global access lines (e.g., global wordlines), not shown in FIG. 2, in a many-to-one relationship. For some embodiments, memory array 114 can be formed over a semiconductor that, for example, can be conductively doped to have a conductivity type, such as a p-type conductivity, e.g., to form a p-well, or an n-type conductivity, e.g., to form an n-well.

Memory array 114 can be arranged in rows (each corresponding to a wordline 202) and columns (each corresponding to a bit line 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select gate 210 (e.g., a field-effect transistor), such as one of the select gates 210₀ to 210_{M} (e.g., that can be source select transistors, commonly referred to as select gate source), and a select gate 212 (e.g., a field-effect transistor), such as one of the select gates 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select gates 210 and 212 can utilize a structure similar to (e.g., the same as) the memory cells 208. The select gates 210 and 212 can represent a number of select gates connected in series, with each select gate in series configured to receive a same or independent control signal.

A source of each select gate 210 can be connected to common source 216. The drain of each select gate 210 can be connected to a memory cell 208₀ of the corresponding NAND string 206. For example, the drain of select gate 210₀ can be connected to memory cell 208₀ of the corresponding NAND string 206₀. Therefore, each select gate 210 can be configured to selectively connect a corresponding NAND string 206 to the common source 216. A control gate of each select gate 210 can be connected to the select line 214.

The drain of each select gate 212 can be connected to the bit line 204 for the corresponding NAND string 206. For example, the drain of select gate 212₀ can be connected to the bit line 204₀ for the corresponding NAND string 206₀. The source of each select gate 212 can be connected to a memory cell 208_{N} of the corresponding NAND string 206. For example, the source of select gate 212₀ can be connected to memory cell 208_{N} of the corresponding NAND string 206₀. Therefore, each select gate 212 can be configured to selectively connect a corresponding NAND string 206 to the corresponding bit line 204. A control gate of each select gate 212 can be connected to select line 215.

The memory array 114 in FIG. 2 can be a quasi-two-dimensional memory array and can have a generally planar structure, e.g., where the common source 216, NAND strings 206 and bit lines 204 extend in substantially parallel planes. Alternatively, the memory array 114 in FIG. 2 can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. The memory cells 208 have their control gates 236 connected to (and in some cases form) a wordline 202.

A column of the memory cells 208 can be a NAND string 206 or a number of NAND strings 206 selectively connected to a given bit line 204. A row of the memory cells 208 can be memory cells 208 commonly connected to a given wordline 202. A row of memory cells 208 can, but need not, include all the memory cells 208 commonly connected to a given wordline 202. Rows of the memory cells 208 can often be divided into one or more groups of physical pages of memory cells 208, and physical pages of the memory cells 208 often include every other memory cell 208 commonly connected to a given wordline 202. For example, the memory cells 208 commonly connected to wordline 202_{N} and selectively connected to even bit lines 204 (e.g., bit lines 204₀, 204₂, 204₄, etc.) can be one physical page of the memory cells 208 (e.g., even memory cells) while memory cells 208 commonly connected to wordline 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅ are not explicitly depicted in FIG. 2, it is apparent from the figure that the bit lines 204 of the memory array 114 can be numbered consecutively from bit line 204₀ to bit line 204_{M}. Other groupings of the memory cells 208 commonly connected to a given wordline 202 can also define a physical page of memory cells 208. For certain memory devices, all memory cells commonly connected to a given wordline can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to wordlines 202₀-202_{N} (e.g., all NAND strings 206 sharing common wordlines 202). Unless expressly distinguished, a reference to a page of memory cells herein refers to the memory cells of a logical page of memory cells. Although the example of FIG. 2 is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

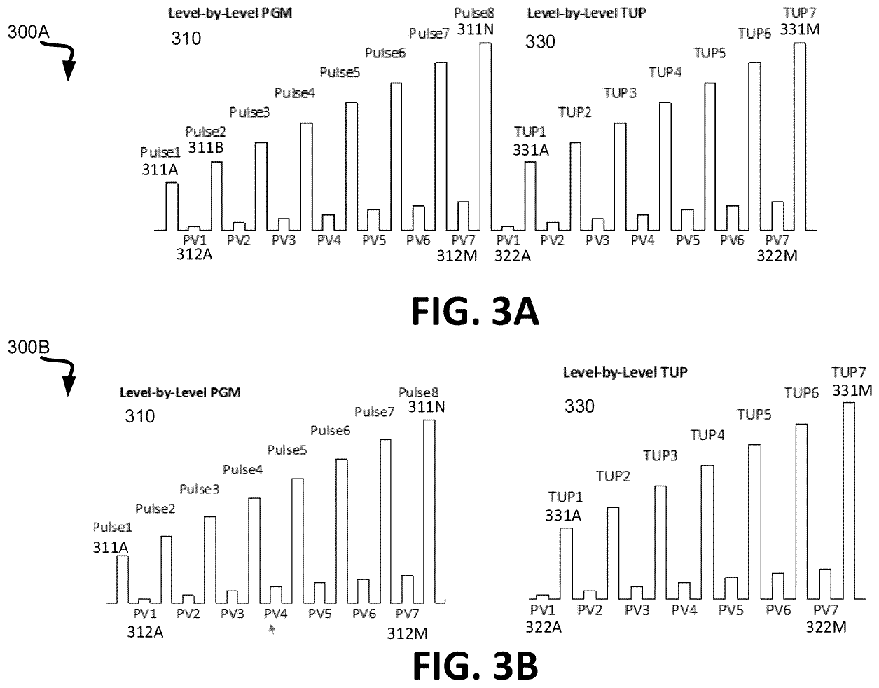

FIG. 3A and FIG. 3B illustrate a primary program operation 310 and secondary program operation 320 (e.g., a touch-up program operation), according to some aspects of the disclosure. The primary program operation and the secondary program operation can be level-by-level program operations. In some embodiments, the primary program operation 310 and secondary program operation 320 can be sequential, as illustrated in 300A of FIG. 3A. In some embodiments, the primary program operation 310 and secondary program operation 320 can be non-sequential (e.g., there can be a break between the program operations) as illustrated in 300B of FIG. 3B. It can be noted that while FIG. 3A and FIG. 3B illustrate a primary program operation 310 and secondary program operation 320 for TLC memory cells, similar program operations can be performed on MLCs, QLCs, etc.

The primary program operation 310 can include primary program pulses 311 (e.g., pulse 1 311A, pulse8 311N, etc.) and program verify pulses 312 (e.g., PV1 313A, PV7 312M, etc.). In the illustrated primary program operation 310 for a TLC memory device, the primary program pulses 311 can be applied to program memory cells of respective voltage distributions (e.g., level zero (L0) through level seven (L7)). The program verify pulses 312 can be applied to the memory cells of respective voltage distributions to verify the success of the previously performed primary program pulse 311. In some embodiments, the voltage values of the primary program pulses 311 can be greater than or equal to a desired voltage threshold corresponding to a respective voltage distribution. In the illustrated example for a TLC memory device, an initial pulse (e.g., pulse1 311A) can be applied to sample the wordline to be programmed. Subsequent primary program pulses 311 can be applied to voltage distributions L1 through L7. Thus, eight primary program pulses 311 and seven program verify pulses 312 can be applied for the primary program operation.

The secondary program operation 320 can include sensing pulses 323A (e.g., PV1 323A, PV7 322M, and touch-up program pulses 321 (e.g., TUP1 321A, TUP7 321M, etc.). In the illustrated secondary program operation 320 for the TLC memory device, the sensing pulses 321 can be applied to sense which cells of a programmed voltage distribution (e.g., cells corresponding to a level 1 (L1), level two (L2), etc.) have voltage values below a voltage threshold of the voltage distribution. The voltage value of the sensing pulses 322 can be the same as the voltage value of the corresponding verify pulses. For example, the voltage value of PV1 323A can be the same as, or similar to the voltage value of PV1 313A, and the voltage value of PV7 322M can be the same as, or similar to the voltage value of PV7 312M. An analog bitline voltage can be determined based on data obtained from the sensing pulse 312. Once determined, the analog bitline voltage can be applied during the subsequent touch-up program pulse 321A such that the voltage values of cells below the threshold voltage increase, while the voltage values of cells at or above the voltage threshold remain the same or similar. The voltage values of the touch-up program pulses 321 can be between two primary program pulse 311 voltage values from the primary program operation 310 performed at adjacent voltage distributions (e.g., L1 and L2). For example, the voltage value of TUP1 321A can be between the voltage values for pulse1 311A, and pulse2 311B. In some embodiments, the voltage value of the touch-up program pulse 321 is configurable. As illustrated, the primary programing operation 310 has seven programing pulses 311 (corresponding to voltage level zero (L0) through level seven (L7)) with a program verify pulse 312 in between each primary program pulse 311, for seven total program verify pulses.

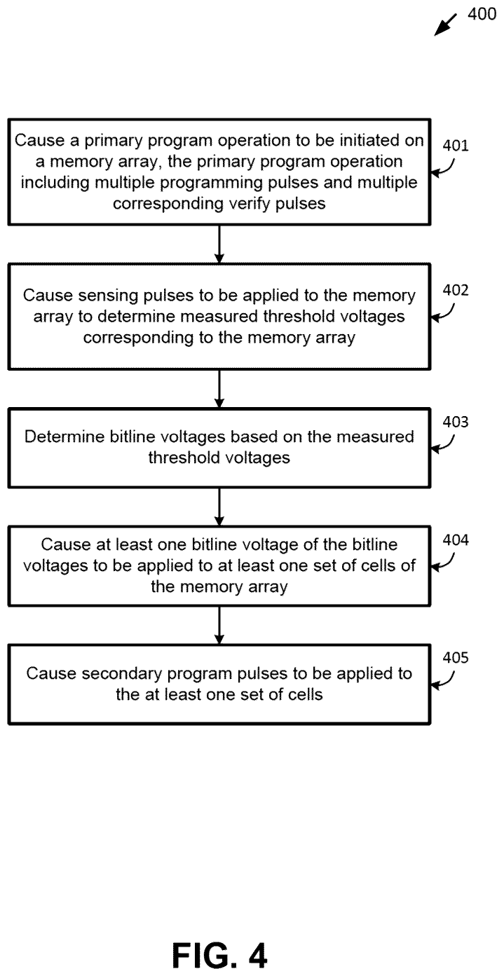

FIG. 4 is a flow diagram of an example method for level-by-level touch-up programming in a memory device of a memory sub-system in accordance with aspects of the disclosure. The method 400 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 400 is performed by the local media controller 135 and/or level-by-level touch-up component 134 of FIG. 1A. In some embodiments, the memory sub-system controller 115 and/or touch-up manager component 114 of FIG. 1A can cause the method 400 to be performed (e.g., the method 400 can be caused to be performed). Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 401, a program operation is initiated. For example, the processing logic (e.g., level-by-level touch-up component 134) can cause a program operation to be initiated on a memory array, such as memory array 114, of memory device 130. In one embodiment, the program operation can be a primary program operation that includes multiple program pulses and multiple corresponding verify pulses. In some embodiments, a first program pulse can be a sampling pulse for a first voltage distribution (e.g., an L1). For example, a primary program operation for a TLC memory device can have eight program pulses-a first program pulse to sample the first voltage distribution, and seven subsequent program pulses to program the each of the voltage distributions (e.g., L1 through L7). The verify pulses can determine a success of the primary program pulse. In some embodiments, information from the verify pulse can be graphically reflected as a voltage distribution (e.g., quantities of memory cells at each voltage value within the voltage distribution). Sensing pulses are performed after a programing pulse. For example, a primary program operation for a TLC memory device can have seven sensing pulses-one sensing pulse applied after each program pulse to program each of the voltage distributions (e.g., L1 through L7).

At operation 402, a secondary program operation is initiated when a sensing pulse is applied. For example, the processing logic causes the secondary program operation to be initiated on the memory array 114. In some embodiments, the secondary program operation is performed on memory cells that have previously been programmed (e.g., programmed memory cells). The sensing pulse can determine measured threshold voltages corresponding to respective sets of cells of the memory array. In some embodiments, multiple sensing pulses are applied. One sensing pulse can be applied for each respective voltage distribution of the memory device. Sensing pulses are performed before a secondary programing pulse. For example, a secondary program operation for a TLC memory device can have seven sensing pulses-one sensing pulse applied before a secondary program pulse used to program each of the voltage distributions (e.g., L1 through L7). In some embodiments, the voltage value of the sensing pulse can be the same as the voltage value of a corresponding verify pulse (e.g., performed during a primary program operation). For example, if a verify pulse performed on an L1 voltage distribution has a voltage value of 0.5 volts, a sensing pulse performed on the L1 voltage distribution can have a voltage value the same as or similar to 0.5 volts.

At operation 403, bitline voltages are determined. For example, the processing logic can determine bitline voltages to be applied to the memory array 114 based on the measured threshold voltages obtained at the operation 402. In some embodiments, the bitline voltages can correspond to the respective sets of cells based on the threshold voltages of a voltage distribution. The bitline voltages can be determined based on a difference between the measured voltages of memory cells corresponding to a voltage distribution and the threshold voltage of the voltage distribution. As described above, the bitline voltages (e.g., voltages for respective bitlines) can be analog voltages. By using an analog bitline voltage, the voltage values of memory cells within a voltage distribution can be selectively altered or unaltered. The analog bitline voltage can be determined such that memory cells that have voltage values at or above the threshold voltage receive an inhibit bitline voltage (preventing the voltages of the memory cells from changing significantly) while memory cells that have voltage values below the threshold voltage receive a bitline voltage that facilitates an increase in the voltage value of the memory cell.

At operation 404, bitline voltages are applied. For example, the processing logic can cause at least one bitline voltage of multiple bitline voltages to be applied to at least one set of cells of the memory array 114. In some embodiments, multiple bitline voltages are applied to multiple sets of cells of the memory array. In some embodiments, certain bitline voltages are applied to memory cells that have a measured voltage that is below a threshold voltage of the voltage distribution. When a program pulse is applied, the bitline voltage can cause the measured voltage to shift closer to the threshold voltage. For example, if a threshold voltage for a voltage distribution is 1.1 volts and a memory cell has a voltage of 0.9 volts, the applied bitline voltage can allow the memory cell voltage to shift up from 0.9 volts closer to 1.1 volts. In some embodiments, inhibiting bitline voltages are applied to memory cells that have a measured voltage that is at or above the threshold voltage of the voltage distribution. When a program pulse is applied, the inhibiting bitline voltage can cause the memory cell voltage to remain at or near the memory cell voltage. For example, if a threshold voltage for a voltage distribution is 1.1 volts and the voltage of the memory cell is 1.2 volts, the applied bitline voltage can allow the memory cell voltage to remain at or near 1.2 volts.

At operation 405, a secondary program pulse is applied. For example, the processing logic can apply a secondary program pulse to at least one set of cells of the memory array 114. In some embodiments, the secondary program pulse can be applied to sets of cells at each respective voltage distribution. For example, in a TLC memory device, seven secondary program pulses can be applied to program voltage distributions L1 through L7. In some embodiments, the number of secondary program pulses performed during the secondary program operation can be less than the number of primary program pulses performed during the primary program operation. In some embodiments, the voltage value of the secondary program pulse is adjustable based on operating conditions of the memory device. Operating conditions can include, for example, temperature, time, duration between program operations (e.g., between a primary program operation and a secondary program operation), duration between program pulses (e.g., within a primary program operation or secondary program operation), etc. In some embodiments, the voltage value of the secondary program pulses can be based on the voltage values of primary program pulses. For example, a voltage value of a secondary program pulse for the L1 voltage distribution can be between the voltage value of a primary program pulse for the L1 voltage distribution and the voltage value of a primary program pulse for the L2 voltage distribution. In some embodiments, the difference between the voltage values of secondary program operations is a constant.

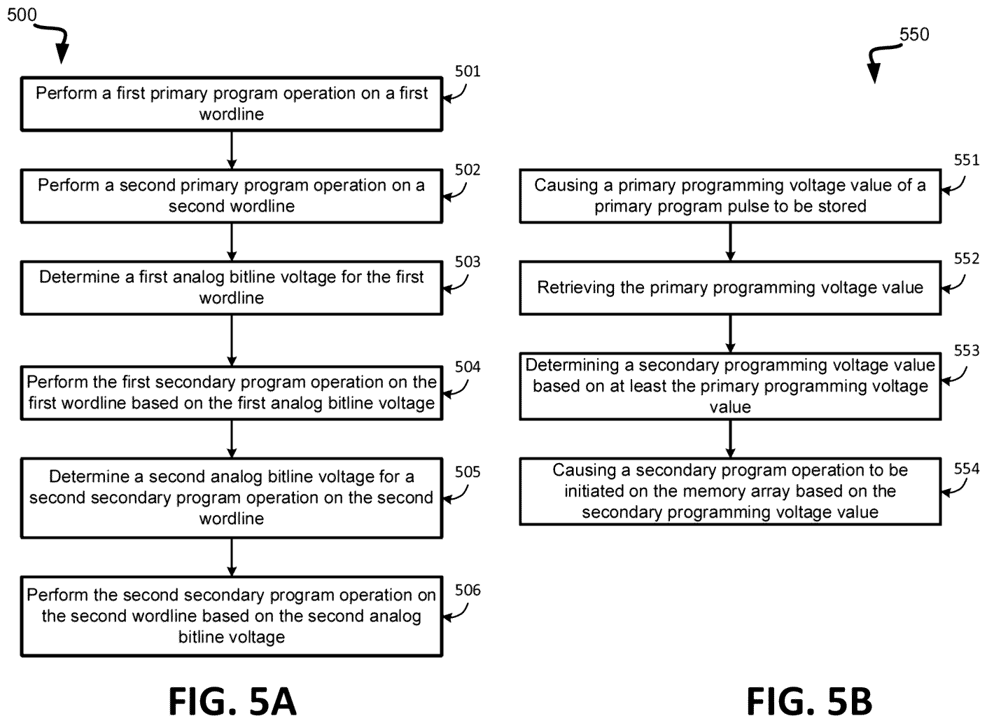

FIG. 5A and FIG. 5B are flow diagrams of an example method for level-by-level touch up programming in a memory device of a memory sub-system according to some aspects of the disclosure. The method 500 and/or the method 550 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 500 and/or the method 550 is performed by the local media controller 135 and/or level-by-level touch-up component 134 of FIG. 1A. In some embodiments, the memory sub-system controller 115 and/or touch-up manager component 114 of FIG. 1A can cause the method 500 and/or the method 550 to be performed (e.g., the methods 500 and 550 can be caused to be performed). Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 501, a primary program operation is performed. For example, the processing logic (e.g., level-by-level touch-up component 134) can cause a first primary program operation to be performed on a first wordline of the memory array 114. In some embodiments, the primary program operation can be a level-by-level program operation, or another type of program operation.

At operation 502, another primary program operation is performed. For example, the processing logic can cause a second primary program operation to be performed on a second wordline of the memory array 114. In some embodiments, the second wordline is adjacent to the first wordline. In other embodiments, the second wordline is not adjacent to the first wordline. In some embodiments, additional primary program operations are performed on additional wordlines of the memory array 114. For example, the processing logic can cause a third primary program operation to be performed on a third wordline of the memory array 114, etc.

At operation 503, an analog bitline voltage is determined. For example, the processing logic can determine a first analog bitline voltage for the first wordline of the memory array 114. In some embodiments, the first analog bitline voltage can be determined as described above with reference to FIG. 4. In some embodiments, a single analog bitline voltage can apply different bitline voltages to various sets of memory cells in the memory array 114 based on the voltage level of memory cells in the set of cells. For example, memory cells with voltage values above a threshold voltage of the voltage distribution can have a bitline voltage applied that inhibits the change in memory cell voltage, while memory cells with voltage values below the threshold voltage can have a bitline voltage applied that facilitates the change in memory cell voltage.

At operation 504, a secondary program operation is performed. For example, the processing logic can cause a first secondary program operation to be performed using the first analog bitline voltage. In some embodiments, the first secondary program operation is performed at the first wordline of the memory array 114. The first secondary program operation can be referred to as a touch-up program operation, or touch-up operation. In some embodiments, the touch-up operation is performed to increase RWB between voltage distributions in the memory array 114.

At operation 505, another analog bitline voltage is determined. For example, the processing logic can determine a second analog bitline voltage for the second wordline of the memory array 114. In some embodiments, the second analog bitline voltage can be determined in the same way as the first analog bitline voltage, as described above with reference to FIG. 4. In some embodiments, as applicable, subsequent analog bitline voltages can be determined for subsequent wordlines of the memory array 114 (e.g., a third analog bitline voltage for a third wordline, etc.).

At operation 506, another secondary program operation is performed. For example, the processing logic can cause a second secondary program operation to be performed using the second analog bitline voltage. In some embodiments, the second secondary program operation is performed at the second wordline of the memory array 114. As applicable, subsequent program operations can be performed at subsequent wordlines of the memory array 114 (e.g., a third secondary program operation performed at a third wordline, etc.).

The method 550 can be performed in conjunction with the method 300 and the method 500. In some embodiments, the method 550 is performed when there is a gap, or delay between the primary program operation and the secondary program operation. For example, in the method 500, there is a gap between performing the first primary program operation (e.g., a second primary program operation is performed) and performing the first secondary program operation. In some embodiments, the quantity of wordlines programmed between a primary program operation on a first wordline and a secondary program operation on the first wordline is based on a quantity of wordlines, or a time duration between program operations.

At operation 551, a primary programming voltage value is stored. For example, the processing logic can cause a primary programming voltage value of a primary program pulse to be stored. In some embodiments, a primary program pulse can be any program pulse performed during a primary program operation, and the primary program pulse voltage value can be the corresponding voltage value of the program pulse. In some embodiments, the primary program pulse voltage value is a voltage value of a first-in-time primary program pulse (e.g., a program pulse performed to program the L1 voltage distribution). The primary programming voltage value can be stored as an entry in a data table. In some embodiments, the primary programming voltage value corresponding to multiple wordlines can be stored as entries in the data table.

At operation 552, the primary programming voltage value is retrieved. For example, the processing logic can cause the primary programming voltage value to be retrieved. In some embodiments, the primary programming voltage value can be retrieved from the data table. In some embodiments, multiple primary programming voltage values corresponding to multiple wordlines can be stored. In some embodiments, a primary programming voltage value can correspond to multiple wordlines. In some embodiments, primary programming voltage values for programming pulses can be related by a constant value. For example, a primary programming voltage value (e.g., a program voltage value for an L1 voltage distribution) can be separated from a program voltage value for an L2 voltage distribution by the constant value, and the program pulse voltage value for the L2 voltage distribution can be separated from a program pulse voltage value for the L3 voltage distribution by the constant value, etc.

At operation 553, a secondary program pulse voltage value is determined. For example, the processing logic can determine a secondary program pulse voltage value based at least on the primary programming voltage value. In some embodiments, the secondary program pulse voltage value is a constant value away from the primary program pulse voltage value. In some embodiments, the secondary program pulse voltage value corresponds to an entry in a data table indexed by primary program pulse voltage values. That is, primary program pulse voltage values can correspond to secondary program pulse voltage values in a predetermined table (e.g., a table programmed to memory during manufacturing and/or production of the memory device and/or memory sub-system).

At operation 554, a secondary program operation is initiated. For example, the processing logic can cause a secondary program operation to be initiated on the memory array 114 based on the secondary program pulse voltage value. In some embodiments, the secondary program operation can include multiple secondary program pulses, each secondary program pulse corresponding to a voltage distribution (e.g., L1 through L7).

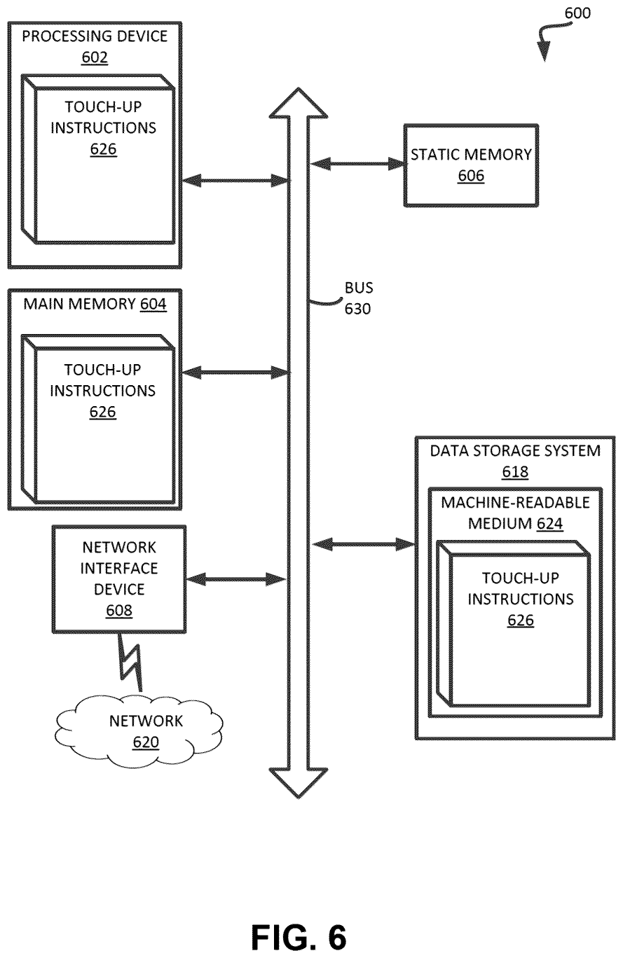

FIG. 6 illustrates an example machine of a computer system 600 within which a set of instructions, for causing the machine to perform any one or more of the methodologies discussed herein, can be executed. In some embodiments, the computer system 600 can correspond to a host system (e.g., the host system 120 of FIG. 1A) that includes, is coupled to, or utilizes a memory sub-system (e.g., the memory sub-system 110 of FIG. 1A) or can be used to perform the operations of a controller (e.g., to execute an operating system to perform operations corresponding to the local media controller 135 of FIG. 1A). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random access memory (DRAM) such as synchronous DRAM (SDRAM) or RDRAM, etc.), a static memory 606 (e.g., flash memory, static random access memory (SRAM), etc.), and a data storage system 618, which communicate with each other via a bus 630.

Processing device 602 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 602 can also be one or more special-purpose processing devices such as an application specific integrated circuit (ASIC), a field programmable gate array (FPGA), a digital signal processor (DSP), network processor, or the like. The processing device 602 is configured to execute touch-up instructions 626 for performing the operations and steps discussed herein. The computer system 600 can further include a network interface device 608 to communicate over the network 620.

The data storage system 618 can include a machine-readable storage medium 624 (also known as a computer-readable medium) on which is stored one or more sets of touch-up instructions 626 or software embodying any one or more of the methodologies or functions described herein. The touch-up instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage system 618, and/or main memory 604 can correspond to the memory sub-system 110 of FIG. 1A.

In one embodiment, the touch-up instructions 626 include instructions to implement functionality corresponding to the local media controller 135 and/or the level-by-level touch-up component 134 of FIG. 1A. While the machine-readable storage medium 624 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A memory device comprising:
a memory array comprising a plurality of memory cells; and
control logic, operatively coupled with the memory array to perform operations comprising:
causing a primary program operation to be initiated on the memory array, the primary program operation comprising a plurality of primary program pulses and a plurality of corresponding verify pulses; and
causing a secondary program operation to be initiated on the memory array, the secondary program operation comprising:
causing a plurality of sensing pulses to be applied to the memory array to determine a plurality of measured threshold voltages corresponding to the memory array;
determining a plurality of bitline voltages based on the plurality of measured threshold voltages;
causing at least one bitline voltage of the plurality of bitline voltages to be applied to at least one set of cells of the plurality of memory cells; and
causing a plurality of secondary program pulses to be applied to the at least one set of cells.

2. The memory device of claim 1, wherein a first quantity of the plurality of primary program pulses is greater than a second quantity of the plurality of secondary program pulses.

3. The memory device of claim 1, wherein a first voltage value is used as a voltage value of the plurality of corresponding verify pulses and a voltage value of the plurality of sensing pulses.

4. The memory device of claim 1, wherein a voltage value of a secondary program pulse of the plurality of secondary program pulses is based on a first voltage value of a first primary program pulse of the plurality of primary program pulses, and a second voltage value of a second primary program pulse of the plurality of primary program pulses.

5. The memory device of claim 1, wherein voltage values of respective secondary program pulses of the plurality of secondary program pulses are adjustable based on one or more operating conditions of the memory array.

6. The memory device of claim 1, wherein the primary program operation is a first primary program operation caused to be initiated on a first wordline of the memory array, wherein the secondary program operation is a first secondary program operation cause to be initiated on the first wordline, and wherein the operations of the control logic further comprise:
responsive to completing the first primary program operation on the first wordline, causing a second primary program operation to be initiated on a second wordline of the memory array; and
responsive to completing the first secondary program operation on the first wordline, causing a second secondary program operation to be initiated on the second wordline.

7. The memory device of claim 1, wherein the operations of the control logic further comprise:
causing a primary programming voltage value of a primary program pulse of the plurality of primary program pulses to be stored;
retrieving the primary programming voltage value;
determining a secondary programming voltage value based on at least the primary programming voltage value; and
causing the secondary program operation to be initiated on the memory array based on the secondary programming voltage value.

8. A method comprising:
causing a primary program operation to be initiated on a memory array, the primary program operation comprising a plurality of primary program pulses and a plurality of corresponding verify pulses; and
causing a secondary program operation to be initiated on the memory array, the secondary program operation comprising:
causing a plurality of sensing pulses to be applied to the memory array to determine a plurality of measured threshold voltages corresponding to the memory array;
determining a plurality of bitline voltages based on the plurality of measured threshold voltages;
causing at least one bitline voltage of the plurality of bitline voltages to be applied to at least one set of cells of the memory array; and
causing a plurality of secondary program pulses to be applied to the at least one set of cells.

9. The method of claim 8, wherein a first quantity of the plurality of primary program pulses is greater than a second quantity of the plurality of secondary program pulses.

10. The method of claim 8, wherein a first voltage value is used as a voltage value of the plurality of corresponding verify pulses and a voltage value of the plurality of sensing pulses.

11. The method of claim 8, wherein a voltage value of a secondary program pulse of the plurality of secondary program pulses is based on a first voltage value of a first primary program pulse of the plurality of primary program pulses, and a second voltage value of a second primary program pulse of the plurality of primary program pulses.

12. The method of claim 8, wherein voltage values of respective secondary pulses of the plurality of secondary program pulses are adjustable based on one or more operating conditions of the memory array.

13. The method of claim 8, wherein the primary program operation is a first primary program operation caused to be initiated on a first wordline of the memory array, wherein the secondary program operation is a first secondary program operation cause to be initiated on the first wordline, the method further comprising:
responsive to completing the first primary program operation on the first wordline, causing a second primary program operation to be initiated on a second wordline of the memory array; and
responsive to completing the first secondary program operation on the first wordline, causing a second secondary program operation to be initiated on the second wordline.

14. The method of claim 8, further comprising:
causing a primary programming voltage value of a primary program pulse of the plurality of program pulses to be stored;
retrieving the primary programming voltage value;
determining a secondary programming voltage value based on at least the primary programming voltage value; and
causing the secondary program operation to be initiated on the memory array based on the secondary programming voltage value.

15. A memory device comprising:
a memory array; and
control logic, operatively coupled with the memory array, to perform operations comprising:
causing a set of sensing pulses to be applied to a plurality of programmed memory cells of the memory array to determine a plurality of voltage values corresponding to the plurality of programmed memory cells;
determining a plurality of bitline voltages based on the plurality of voltage values;
causing one or more of the plurality of bitline voltages to be applied to the programmed memory cells; and
causing a plurality of program pulses to be applied to the programmed memory cells.

16. The memory device of claim 15, wherein the operations of the control logic further comprise causing an primary program operation to be performed on the memory array, the primary program operation comprising a plurality of primary program pulses and a plurality of corresponding verify pulses.

17. The memory device of claim 16, wherein a first quantity of the plurality of program pulses is less than a second quantity of the plurality of primary program pulses.

18. The memory device of claim 16, wherein a voltage value of the plurality of corresponding verify pulses is the same as a voltage value of the plurality of sensing pulses.

19. The memory device of claim 16, wherein the primary program operation is a first primary program operation caused to be initiated on a first wordline of the memory array, wherein the program operation is a first touch-up program operation caused to be initiated on the first wordline, and wherein the operations of the control logic further comprise:
responsive to completing the first primary program operation on the first wordline, causing a second primary program operation to be initiated on a second wordline of the memory array; and
responsive to completing the first touch-up program operation on the first wordline, causing a second touch-up program operation to be initiated on the second wordline.

20. The memory device of claim 15, wherein voltage values of program pulses of the plurality of program pulses are adjustable based on one or more operating conditions of the memory array.
